(19) United States
(12) Patent Application Publication
(10) Pub. No.: US 2023/0128880 A1
(43) Pub. Date: Apr. 27, 2023

(54) SEMICONDUCTOR DEVICE, METHOD OF FORMING THE SAME AND LAYOUT DESIGN MODIFICATION METHOD OF THE SAME

(71) Applicant: MEDIATEK INC., Hsinchu City (TW)

(72) Inventor: Po-Chao TSAO, San Jose, CA (US)

(21) Appl. No.: 17/936,553

(22) Filed: Sep. 29, 2022

Related U.S. Application Data
(60) Provisional application No. 63/270,607, filed on Oct. 22, 2021.

(51) Int. Cl. H01L 27/02; G06F 30/392; G06F 30/398

(52) U.S. Cl. CPC H01L 27/0207; G06F 30/392; G06F 30/398

(57) ABSTRACT

A semiconductor device includes a substrate, a first cell and a second cell on the substrate. The first cell includes a first diffusion region in the substrate, a first gate structure over the first diffusion region, and a first contact over the first diffusion region. The first contact is disposed on one side of the first gate structure. The second cell that abuts the first cell includes a second diffusion region in the substrate, a second gate structure over the second diffusion region and a second contact over the second diffusion region. The second contact that is positioned on one side of the second gate structure is adjacent to the first contact of the first cell. The first contact and the second contact are equipotential when the semiconductor device is in operation. The second diffusion region and the first diffusion region form a continuous diffusion region.

### CROSS REFERENCE TO RELATED APPLICATIONS

This application is based on, and claims priority of U.S. Provisional Application No. 63/270,607 filed on Oct. 22, 2021, the entirety of which is incorporated by reference herein.

### BACKGROUND OF THE INVENTION

### Field of the Invention

The present invention relates to a semiconductor device, a method of forming the semiconductor device, and a layout design modification method of the semiconductor device, and in particular it relates to a semiconductor device having cells with modified diffusion regions, a method of forming the semiconductor device, and a layout design modification method to optimize the electrical performance of the cells in the semiconductor device.

### Description of the Related Art

In recent years, advanced integrated circuit (IC) devices have become increasingly multifunctional and have been scaled down in size. Although the scaling down process generally increases production efficiency and lowers the associated costs, it has also increased the complexity of processing and manufacturing IC devices. Also, in designing the layout of the integrated circuits of the cells (e.g. standard cells) in a semiconductor device, a behavioral model that describes the operation to be performed in the semiconductor device and a structural model that describes the connections between the cells must be taken into consideration. There are some problems to be overcome in regards to layout designs of the semiconductor devices when the cells are arranged in certain areas. For example, an abutment arrangement using single diffusion break (SDB) layout design reduces horizontal cell width but induces local layout effect such as LOD (length of diffusion) effect on the cells due to the undesired compressive stress on the transistors of the cells. Typically, the more compressive strain makes p-type metal oxide semiconductor (PMOS) threshold voltage (Vt) decrease and n-type metal oxide semiconductor (NMOS) threshold voltage (Vt) increase. This stress-related local layout impact makes the performance variation of the cells in the semiconductor device higher.

Although existing semiconductor device layout designs for arranging cells have been adequate for their intended purposes, they have not been entirely satisfactory in all respects.

### BRIEF SUMMARY OF THE INVENTION

Some embodiments of the present disclosure provide semiconductor devices. An exemplary embodiment of a semiconductor device includes a substrate, a first cell and a second cell on the substrate. The first cell includes a first diffusion region in the substrate, a first gate structure over the first diffusion region, and a first contact over the first diffusion region. The first contact is disposed on one side of the first gate structure. The second cell is adjacent to the first cell. The second cell includes a second diffusion region in the substrate, a second gate structure over the second diffusion region and a second contact over the second diffusion region. The second contact is positioned on one side of the second gate structure. The second contact of the second cell is adjacent to the first contact of the first cell. Also, the first contact and the second contact are equipotential when the semiconductor device is in operation. According to the embodiments, the second diffusion region and the first diffusion region form a continuous diffusion region.

Some embodiments of the present disclosure provide a method of forming a semiconductor device. First, a substrate is provided. Then, a first cell and a second cell are formed. The first cell includes a first diffusion region in the substrate, a first gate structure over the first diffusion region and a first contact over the first diffusion region. The first contact is disposed on one side of the first gate structure. Also, the second cell is formed adjacent to the first cell. The second cell includes a second diffusion region in the substrate, wherein the second diffusion region and the first diffusion region form a continuous diffusion region. The second cell further includes a second gate structure over the second diffusion region and a second contact over the second diffusion region. The second contact is disposed on one side of the second gate structure. The second contact is adjacent to the first contact of the first cell. The first contact and the second contact are equipotential when the semiconductor device is in operation.

Some embodiments of the present disclosure provide semiconductor device layout design modification method. An exemplary embodiment of a semiconductor device layout design modification method includes receiving an initial layout for cutting adjacent diffusion regions of a first cell and a second cell of a semiconductor device; verifying a first contact of the first cell and a second contact of the second cell that is arranged adjacent to the first contact using a processor, wherein the first contact and the second contact are equipotential when the semiconductor device is in operation; and altering the initial layout to generate a modified layout by uncutting a first diffusion region under the first contact and a second diffusion region under the second contact using the processor, wherein the first diffusion region and the second diffusion region form a continuous diffusion region in the modified layout.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a top view of a cell of a semiconductor device, in accordance with some embodiments of the present disclosure.

FIG. 2 illustrates a flow of an exemplified layout design modification method for a semiconductor device, in accordance with some embodiments of the present disclosure.

FIG. 3A is a top view of two cells of a semiconductor device before an abutment arrangement is implemented, in accordance with some embodiments of the present disclosure.

FIG. 3B is a top view of the semiconductor device including the cells of FIG. 3A in the abutment arrangement, in accordance with some embodiments of the present disclosure.

FIG. 4 is a top view of a semiconductor device including cells with optimized configurations in an abutment arrangement, in accordance with some embodiments of the present disclosure.

FIG. 5A-FIG. 5D illustrate a method of generating a modified layout in the abutment arrangement for forming a semiconductor device in accordance with some embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It should be understood that when an element is referred to as being “connected” or “contacting” to another element, it may be directly connected to or contacting the other element, or intervening elements may be present.

Similarly, it should be understood that when an element such as a layer, region or substrate is referred to as being “on” another element, it can be directly on the other element or intervening elements may be present. It should be understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Furthermore, spatially relative terms, such as “lower”, “under”, “upper”, “above” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same or similar reference numerals or reference designators denote the same or similar elements throughout the specification.

Some embodiments of the disclosure are described. It should be noted that additional procedures can be provided before, during, and/or after the stages described in these embodiments. Some of the stages that are described can be replaced or eliminated for different embodiments. Additional features can be added to the semiconductor device. Some of the features described below can be replaced or eliminated for different embodiments. Although some embodiments are discussed with procedures performed in a particular order, these procedures may be performed in another logical order.

According to some embodiments of the present disclosure, a semiconductor device, a method of forming the semiconductor device and a layout design modification method of the semiconductor device are described below. In some embodiments, a semiconductor device includes several cells (such as standard cells) arranged on a substrate based on an abutment arrangement. According to a layout design modification method of the embodiments, the diffusion regions below adjacent contacts, which are disposed in different cells and equipotential when the semiconductor device is in operation, are uncut and form a continuous diffusion region in the abutment arrangement. This continuous diffusion region under the adjacent contacts that are equipotential during operation of the semiconductor device can prevent the isolation from inducing stress on the transistors of the cells. That is, LOD (length of diffusion) effect on the cells of the semiconductor device in accordance with some embodiments of the present disclosure can be mitigated. Therefore, the electrical performance of the cells (such as the standard cells) of the semiconductor device in accordance with some embodiments of the present disclosure can be optimized and significantly improved.

One or more cells of the semiconductor device and a design layout modification method of the semiconductor device in accordance with some embodiments of the present disclosure are provided below. It should be noted that the present disclosure is not limited to the exemplified structures of the cells of the semiconductor device and exemplified design layout described herein. Those structures and layout design modification method described below are merely for providing examples of the fabrication and configuration of the semiconductor device.

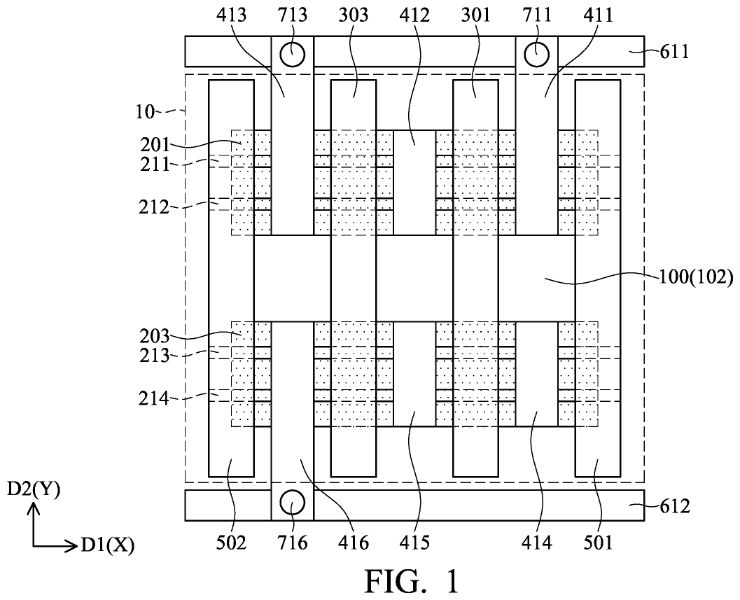

FIG. 1 is a top view of a cell of a semiconductor device, in accordance with some embodiments of the present disclosure. In FIG. 1, a cell (such as a standard cell) 10 includes transistors (such as metal oxide semiconductor transistors) having gate structures and source/drain features at opposite sides of the gate structures. Although fin field-effect transistors (FinFET) are illustrated in FIG. 1, the disclosure is not limited to the exemplified embodiment. The semiconductor device may include planar transistors or three-dimensional transistors such as fin field-effect transistors (FinFETs).

Referring to FIG. 1, in some embodiments, the cell 10 includes the diffusion regions 201 and 203 in the substrate 100. The diffusion region 201 is separated from the diffusion region 203 by an isolation region 102 (such as shallow trench isolations, STI). Diffusion region 201 has the opposite conductivity type of diffusion region 203. In one example, the diffusion region 201 contains n-type dopants and has n-type conductivity. The diffusion region 203 contains p-type dopants and has p-type conductivity. In some embodiments, the diffusion regions 201 and 203 extend in the first direction D1 (such as the X-direction).

In some embodiments, the cell 10 further includes the fins 211, 212, 213 and 214 that are formed on the substrate 100 and protrude from the isolation region 102 (such as STI). In this example, the fins 211 and 212 are formed over the diffusion region 201, and the fins 213 and 214 are formed over the diffusion region 203. The fins 211, 212, 213 and 214 may extend parallel to the longitudinal axis of diffusion region 201 or diffusion region 203. In some embodiments, the fins 211, 212, 213 and 214 extend in the first direction D1 (such as the X-direction). As shown in FIG. 1, adjacent fins 211 and 212 (or adjacent fins 213 and 214) are spaced apart from each other in the second direction D2 (such as the Y-direction). The second direction D2 is different from the first direction D1, and may be perpendicular to the first direction D1. Although two fins over a diffusion region (the diffusion region 201 or the diffusion region 203) are depicted herein, the disclosure is not limited to the exemplified embodiment. In some other embodiments, single fin or more than two fins can be formed over a diffusion region (the diffusion region 201 or the diffusion region 203), depending on the design requirements.

In some embodiments, the cell 10 further includes the gate structures 301 and 303. The gate structures 301 and 303 extend across the fins 211 and 212 over the diffusion region 201. The gate structures 301 and 303 also extend across the fins 213 and 214 over the diffusion region 203. As shown in FIG. 1, adjacent gate structures 301 and 303 are spaced apart from each other in the first direction D1 (such as the X-direction). The gate structures 301 and 303 may extend in the second direction D2 (such as the Y-direction).

In some embodiments, the cell 10 further includes doping regions (not shown) at the fins as source/drain regions. Each of the transistors in the cell 10 includes the fins 211 and 212 (or the fins 213 and 214), the gate structure 301 or the gate structure 303, and the doping regions (i.e. the source/drain regions) at opposite sides of the gate structure 301 or the gate structure 303.

In additions, the cell 10 may be configured as a standard complementary metal oxide semiconductor (CMOS) cell. That is, the cell 10 includes PMOS transistors and NMOS transistors. In some embodiments, the diffusion region 201 has n-type conductivity, and the diffusion region 203 has p-type conductivity. The gate structures 301 and 303, the underlying fins 211 and 212 over the n-type diffusion region 201, and the source/drain regions (not shown) at opposite sides of the gate structures form a plurality of PMOS transistors. The gate structures 301 and 303, the underlying fins 213 and 214 over the p-type diffusion region 203, and the source/drain regions (not shown) at opposite sides of the gate structures form a plurality of NMOS transistors.

In some embodiments, the cell 10 further includes the contacts 411, 412, 413, 414, 415 and 416. As shown in FIG. 1, the contacts 411, 412 and 413 are disposed over the diffusion region 201. The contacts 411, 412 and 413 over the diffusion region 201 are electrically connected to the underlying source/drain region (not shown), and can be referred to as the source/drain contacts 411, 412 and 413. In this example, the contacts 411 and 412 are arranged at opposite sides of the gate structure 301. The contacts 412 and 413 are arranged at opposite sides of the gate structure 303.

In some embodiments, the contacts 411, 412 and 413 extend across the underlying fins 211 and 212 over the diffusion region 201. As shown in FIG. 1, the contacts 411, 412 and 413 are spaced apart from each other in the first direction D1 (such as the X-direction). The contacts 411, 412 and 413 may extend in the second direction D2 (such as the Y-direction).

In addition, the contacts 414, 415 and 416 are disposed over the diffusion region 203. The contacts 414, 415 and 416 over the diffusion region 203 are electrically connected to the underlying source/drain region (not shown), and can be referred to as the source/drain contacts 414, 415 and 416. In this example, the contacts 414 and 415 are arranged at opposite sides of the gate structure 301. The contacts 415 and 416 are arranged at opposite sides of the gate structure 303.

In some embodiments, the contacts 414, 415 and 416 extend across the underlying fins 213 and 214 over the diffusion region 203. As shown in FIG. 1, the contacts 414, 415 and 416 are spaced apart from each other in the first direction D1 (such as the X-direction). Also, the contacts 414, 415 and 416 are spaced apart from the contacts 411, 412 and 413 in the second direction D2 (such as the Y-direction). The contacts 414, 415 and 416 may extend in the second direction D2 (such as the Y-direction).

In some embodiments, the dummy layers 501 and 502 are formed on the substrate. The dummy layers 501 and 502 define the cutting boundaries of the diffusion regions 201 and 203 when the cell 10 is selected for cell abutment arrangement in a layout design. The dummy layers 501 and 502 may be polysilicon layers that are fabricated with polysilicon gates using the same process. As shown in FIG. 1, in some embodiments, the contacts 411 and 414 are adjacent to the dummy layers 501, while the contacts 413 and 416 are adjacent to the dummy layers 502. The dummy layers 501 and 502 may extend in the second direction D2 (such as the Y-direction). In this example, the dummy layers 501 and 502 extend parallel to the longitudinal axis of gate structure 301 or gate structure 303.

In addition, in some embodiments, the contacts 411 and 413 over the diffusion region 201 are electrically connected to a conductive rail 611, and the contact 416 over the diffusion region 203 is electrically connected to another conductive rail 612. The conductive rail 611 may be configured to electrically connect a positive power supply line (e.g., a VCC line), and the conductive rail 612 may be configured to electrically connect a grounding line (e.g., a VSS line). The conductive rail 611 can be referred to as the first power rail, and the conductive rail 612 can be referred to as the second power rail. The conductive rails 611 and 612 may extend in the first direction D1 (such as the X-direction). In this example, the conductive rails 611 and 612 extend parallel to the longitudinal axis of diffusion region 201 or the longitudinal axis of diffusion region 203.

In some embodiments, the conductive rail 611 and the conductive rail 612 are made of the suitable conductive material such as a metal material. Also, the conductive rails 611 and 612 can be formed after the contacts (e.g. source/drain contacts) 411, 412, 413, 414, 415 and 416 are formed. For example, the conductive rails 611 and 612 can be formed as parts of an interconnect structure in the back-end of line (BEOL) process. However, the present disclosure is not limited to the conductive rails 611 and 612 in the BEOL interconnect. The conductive rails 611 and 612 may be formed before the gate structure 301 and the gate structure 303 are formed, depending on the configuration requirements of the to-be-formed semiconductor device in the application. For example, the conductive rails 611 and 612 can be formed in the isolation region 102 (such as buried in the shallow trench isolation (STI)).

In FIG. 1, in some embodiments, the contact 411 (e.g. source/drain contact) extends to the conductive rail 611 and electrically connects the conductive rail 611 through the conductive via 711, so that the source/drain region of a PMOS transistor (having the gate structure 301 in the n-type diffusion region 201) is coupled to the positive power supply line (e.g., a VCC line) through the conductive rail 611 and the corresponding contact 411. Similarly, the contact 413 (e.g. source/drain contact) extends to the conductive rail 611 electrically connects the conductive rail 611 through the conductive via 713, so that the source/drain region of another PMOS transistor (having the gate structure 303 in the n-type diffusion region 201) is coupled to the positive power supply line (e.g., a VCC line) through the conductive rail 611 and the corresponding contact 413, in accordance with some embodiments of the present disclosure. Also, the contact 416 (e.g. source/drain contact) extends to the conductive rail 612 electrically connects the conductive rail 612 through the conductive via 716, so that the source/drain region of a NMOS transistor (having the gate structure 303 in the p-type diffusion region 203) is coupled to the grounding line (e.g., a VSS line) through the conductive rail 612 and the corresponding contact 416, in accordance with some embodiments of the present disclosure.

In an abutment arrangement, a semiconductor device includes several cells (such as standard cells) arranged on a substrate to satisfy the desired goals (such as multiple functions, small size, quick response and another goals). According to a layout design modification method of the embodiment, the diffusion regions below adjacent contacts, which are disposed in different cells and equipotential when the semiconductor device is in operation, are verified and form a continuous diffusion region (i.e. a continuous active region under the equipotential contacts) in the abutment arrangement.

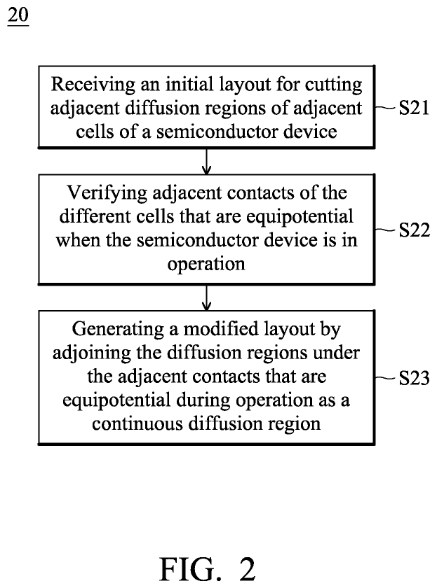

FIG. 2 illustrates a flow of an exemplified layout design modification method for a semiconductor device, in accordance with some embodiments of the present disclosure. Referring to FIG. 2, the method starts with operation S21 in which an initial layout is received. The initial layout defines an initial cut pattern (e.g. the first cut pattern) for cutting adjacent diffusion regions of adjacent cells of a semiconductor device (i.e. a to-be-formed semiconductor device in the application). Then in operation S22, adjacent contacts that each is included in different cells and are equipotential when the semiconductor device is in operation are verified. Continuing to operation S23, the initial layout is altered, and a modified layout is generated. The modified layout defines a modified pattern (e.g. the second cut pattern) by uncutting the diffusion regions under the adjacent contacts that are equipotential during operation. In some embodiments, the modified layout adjoins the diffusion regions under the adjacent contacts that are equipotential during operation as a continuous diffusion region.

In some embodiments, an IC design system (not shown) that includes a processer and a computer-readable storage medium is provided. The processor is communicatively coupled to the computer-readable storage medium. The processor is configured to execute a set of instructions encoded in the computer-readable storage medium during the execution of the modification method in FIG. 2. The computer-readable storage medium stores information required to execute the modification method in FIG. 2 or information generated during the execution of the modification method in FIG. 2. In some embodiments, the processor includes a central processing unit (CPU), a multiprocessor, an application specific integrated circuit (ASIC), a distributed processing system, another suitable processing unit, or a combination thereof. In some embodiments, the computer-readable storage medium includes semiconductor or solid-state memory, removable computer disk, random access memory (RAM), and read-only memory (ROM), hard disk, compact disk (CD), another suitable storage medium or a combination thereof.

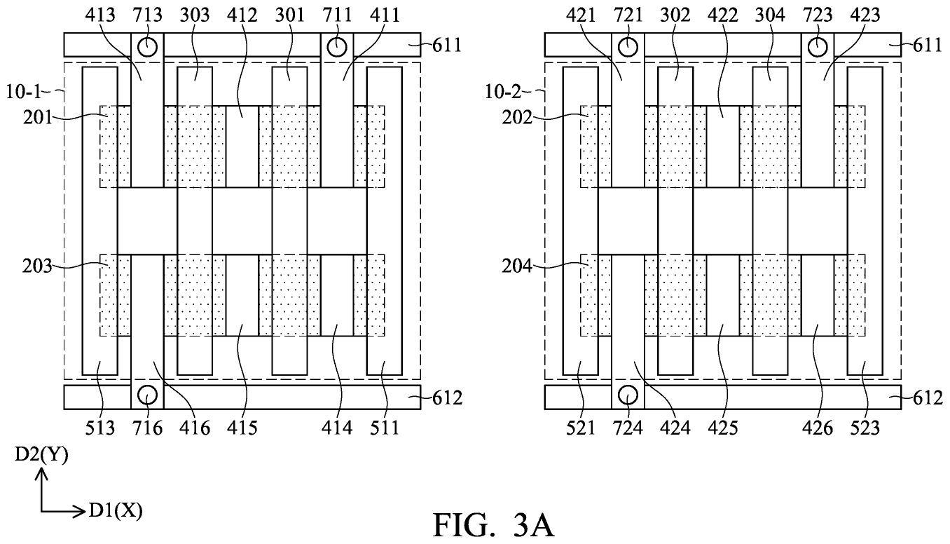

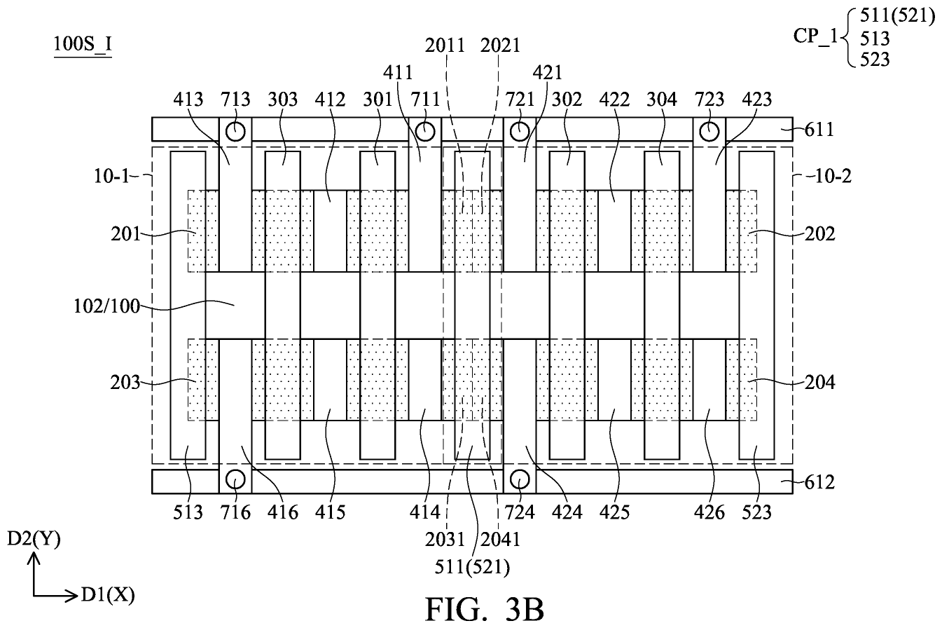

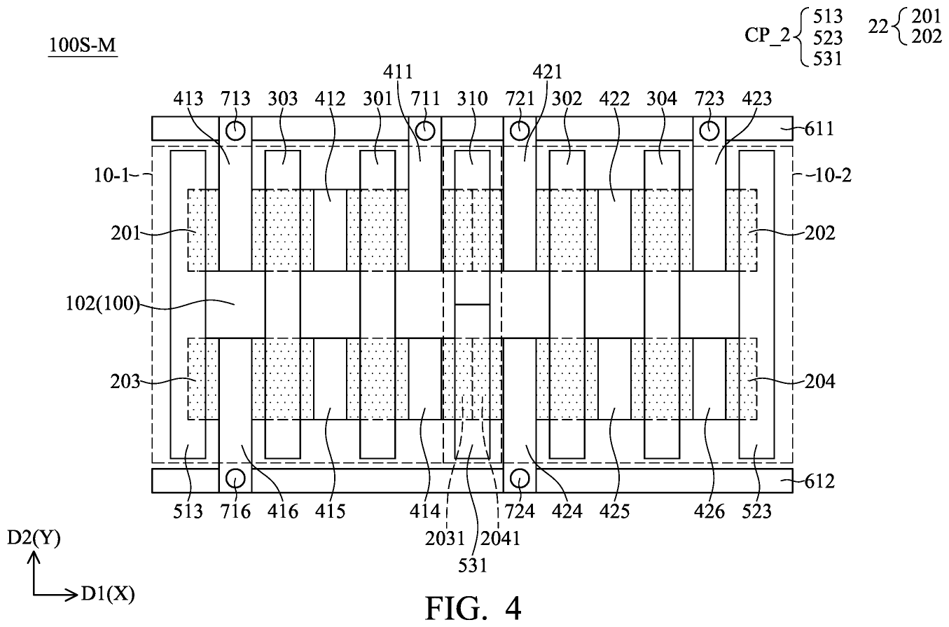

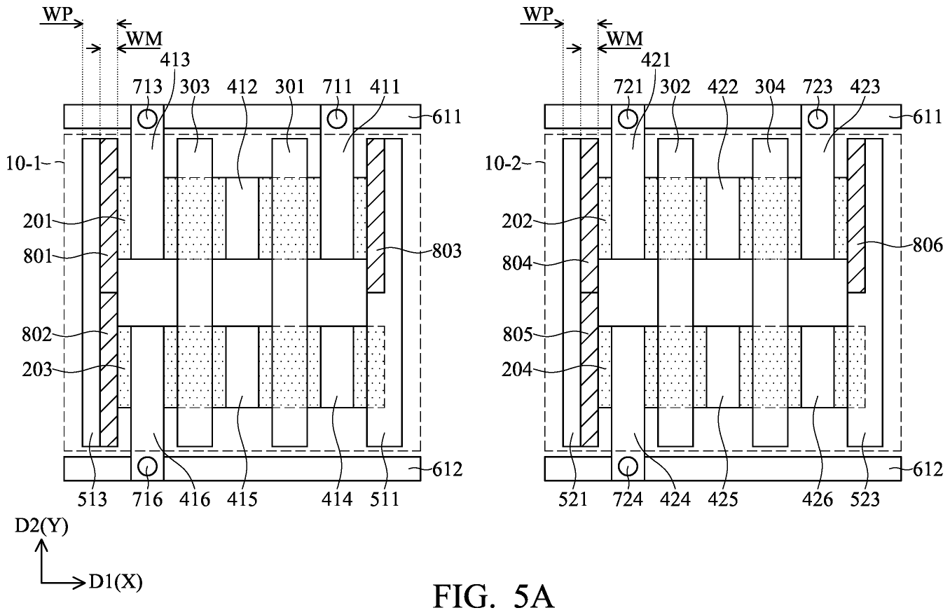

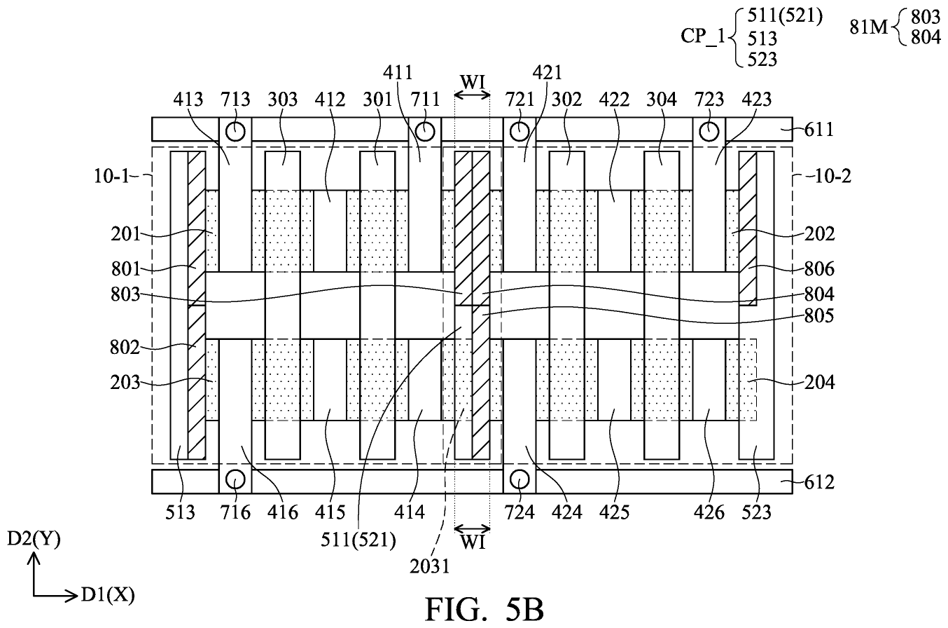

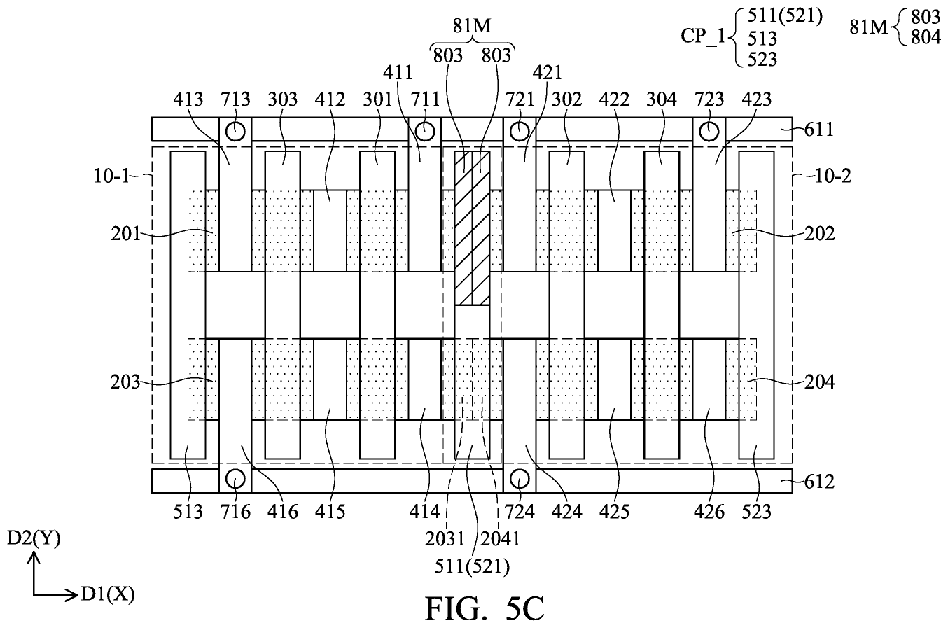

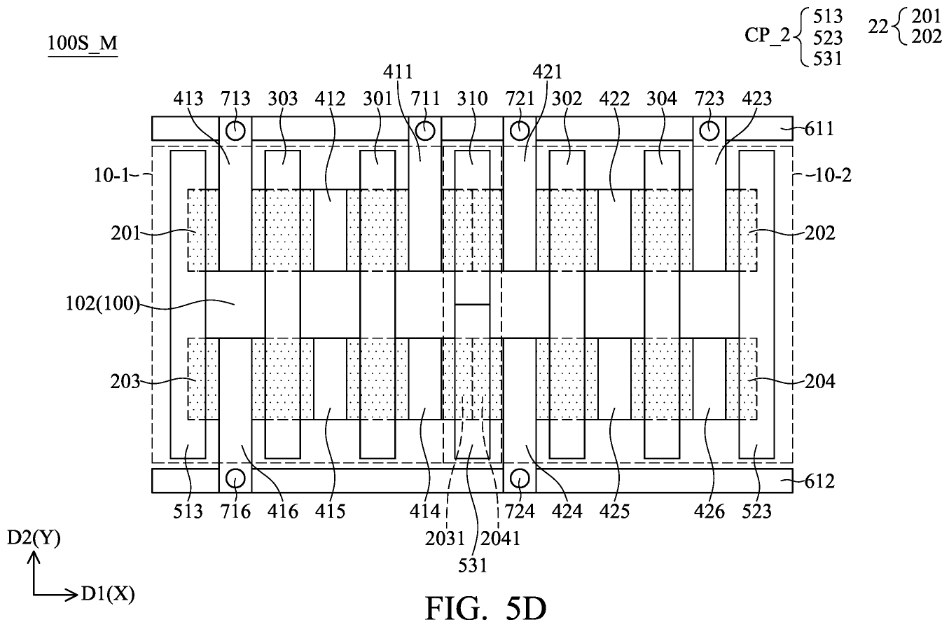

The following exemplary embodiments describe a design layout modification method of a semiconductor device based on an abutment arrangement in accordance with some embodiments of the present disclosure. It should be noted that the fins 211, 212, 213 and 214 depicted in FIG. 1 are omitted in FIG. 3A, FIG. 3B, FIG. 4, FIG. 5A, FIG. 5B, FIG. 5C and FIG. 5D for clarity of illustration.

Corresponding to operation S21 of FIG. 2, FIG. 3A is a top view of two cells of a semiconductor device before an abutment arrangement is implemented, in accordance with some embodiments of the present disclosure. FIG. 3B is a top view of the semiconductor device including the cells of FIG. 3A in the abutment arrangement, in accordance with some embodiments of the present disclosure.

In addition, it should be noted that similar or the same reference numbers are used to designate the similar or the identical features/components in FIG. 3A, FIG. 3B and FIG. 1, and the details of the similar or the identical features/components (such as the structures, materials and configurations thereof) may not repeated herein.

Referring to FIG. 3A, the first cell 10-1 and the second cell 10-2 are provided. In this embodiment, each of the first cell 10-1 and the second cell 10-2 in FIG. 3A is configured as the cell 10 in FIG. 1. It should be noted that the present invention is not limited in this embodiment. In the present disclosure, the configurations of the cells in the to-be-formed semiconductor device in the application may be different from the configuration of the cell 10 in FIG. 1.

In some embodiments, the first cell 10-1 includes the first diffusion region 201 and the third diffusion region 203 in the substrate 100. The second cell 10-2 includes the second diffusion region 202 and the fourth diffusion region 204 in the substrate 100.

As shown in the first cell 10-1 of FIG. 3A, the first diffusion region 201 is separated from the third diffusion region 203 by the isolation region 102 (such as STI). The first diffusion region 201 has the opposite conductivity type of the third diffusion region 203. In one example, the first diffusion region 201 contains n-type dopants and has n-type conductivity, and the third diffusion region 203 contains p-type dopants and has p-type conductivity. In some embodiments, the first diffusion region 201 and the third diffusion region 203 are spaced apart from each other in the second direction D2 (such as the Y-direction) and extend in the first direction D1 (such as the X-direction).

As shown in the second cell 10-2 of FIG. 3A, the second diffusion region 202 is separated from the fourth diffusion region 204 by the isolation region 102 (such as STI). The second diffusion region 202 has the opposite conductivity type of the fourth diffusion region 204. In one example, the second diffusion region 202 contains n-type dopants and has n-type conductivity, and the fourth diffusion region 204 contains p-type dopants and has p-type conductivity. In some embodiments, the second diffusion region 202 and the fourth diffusion region 204 are spaced apart from each other in the second direction D2 (such as the Y-direction) and extend in the first direction D1 (such as the X-direction).

In some embodiments, the first cell 10-1 further includes the first gate structures 301 and 303. The first gate structures 301 and 303 extend across the first diffusion region 201 and the third diffusion region 203. As shown in FIG. 3A, the first gate structures 301 and 303 are spaced apart from each other in the first direction D1 (such as the X-direction), and extend in the second direction D2 (such as the Y-direction).

Similarly, the second cell 10-2 further includes the second gate structures 302 and 304. The second gate structures 302 and 304 extend across the second diffusion region 202 and the fourth diffusion region 204. As shown in FIG. 3A, the second gate structures 302 and 304 are spaced apart from each other in the first direction D1 (such as the X-direction), and extend in the second direction D2 (such as the Y-direction).

In some embodiments, the first cell 10-1 further includes doping regions (not shown) at the fins as source/drain regions. Each of the transistors in the first cell 10-1 includes the fins (not shown), the first gate structure 301 (or the first gate structure 303), and the doping regions (i.e. the source/drain regions) at opposite sides of the first gate structure 301 (or the first gate structure 303).

In additions, the first cell 10-1 may be configured as a standard complementary metal oxide semiconductor (CMOS) cell. That is, the first cell 10-1 includes PMOS transistors and NMOS transistors. In some embodiments, the first diffusion region 201 has n-type conductivity, and the third diffusion region 203 has p-type conductivity. The first gate structures 301 and 303, the underlying fins (not shown) over the n-type first diffusion region 201, and the source/drain regions (not shown) at opposite sides of the first gate structures form a plurality of PMOS transistors. The first gate structures 301 and 303, the underlying fins (not shown) over the p-type third diffusion region 203, and the source/drain regions (not shown) at opposite sides of the first gate structures 301 and 303 form a plurality of NMOS transistors.

In some embodiments, the second cell 10-2 further includes doping regions (not shown) at the fins as source/drain regions. Each of the transistors in the second cell 10-2 includes the fins (not shown), the second gate structure 302 (or the second gate structure 304), and the doping regions (i.e. the source/drain regions) at opposite sides of the second gate structure 302 (or the second gate structure 304).

In additions, the second cell 10-2 may be configured as a standard CMOS cell. That is, the second cell 10-2 includes PMOS transistors and NMOS transistors. In some embodiments, the second diffusion region 202 has n-type conductivity, and the fourth diffusion region 204 has p-type conductivity. The second gate structures 302 and 304, the underlying fins (not shown) over the n-type second diffusion region 202, and the source/drain regions (not shown) at opposite sides of the second gate structures form a plurality of PMOS transistors. The second gate structures 302 and 304, the underlying fins (not shown) over the p-type fourth diffusion region 204, and the source/drain regions (not shown) at opposite sides of the second gate structures 302 and 304 form a plurality of NMOS transistors.

In some embodiments, the first cell 10-1 further includes the contacts 411, 412 and 413 disposed over the first diffusion region 201. The first cell 10-1 further includes the contacts 414, 415 and 416 disposed over the second diffusion region 203. The contacts 411, 412, 413, 414, 415 and 416 are electrically connected to the underlying source/drain region (not shown), and can be referred to as the source/drain contacts. In this example, the contacts 411 and 412 are arranged at opposite sides of the first gate structure 301. The contacts 412 and 413 are arranged at opposite sides of the first gate structure 303. As shown in FIG. 3A, the contacts 411, 412 and 413 over the first diffusion region 201 are spaced apart from each other in the first direction D1 (such as the X-direction), and the contacts 414, 415 and 416 over the third diffusion region 203 are also spaced apart from each other in the first direction D1. The contacts 411, 412, 413, 414, 415 and 416 may extend in the second direction D2 (such as the Y-direction).

In addition, in the first cell 10-1 of some embodiments, the contacts 411 and 413 over the first diffusion region 201 are electrically connected to the first conductive rail 611 through the conductive vias 711 and 713, respectively. The contact 416 over the third diffusion region 203 is electrically connected to the second conductive rail 612 through the conductive via 716. The first conductive rail 611 can be referred to as the first power rail, and the second conductive rail 612 can be referred to as the second power rail. The first conductive rail 611 and the second conductive rail 612 can be made of the suitable conductive material such as metal.

In some embodiments, the second cell 10-2 further includes the contacts 421, 422 and 423 disposed over the second diffusion region 202. The second cell 10-2 further includes the contacts 424, 425 and 426 disposed over the fourth diffusion region 204. The contacts 421, 422, 423, 424, 425 and 426 are electrically connected to the underlying source/drain region (not shown), and can be referred to as the source/drain contacts. In this example, the contacts 421 and 422 are arranged at opposite sides of the second gate structure 302. The contacts 422 and 423 are arranged at opposite sides of the second gate structure 304. As shown in FIG. 3A, the contacts 421, 422 and 423 over the second diffusion region 202 are spaced apart from each other in the first direction D1 (such as the X-direction), and the contacts 424, 425 and 426 over the fourth diffusion region 204 are also spaced apart from each other in the first direction D1. The contacts 421, 422, 423, 424, 425 and 426 may extend in the second direction D2 (such as the Y-direction).

In addition, in the second cell 10-2 of some embodiments, the contacts 421 and 423 over the second diffusion region 202 are electrically connected to the first conductive rail 611 through the conductive vias 721 and 723, respectively. The contact 424 over the fourth diffusion region 204 is electrically connected to the second conductive rail 612 through the conductive via 724. The first conductive rail 611 can be referred to as the first power rail, and the second conductive rail 612 can be referred to as the second power rail. The first conductive rail 611 and the second conductive rail 612 can be made of the suitable conductive material such as metal.

In the first cell 10-1 of some embodiments, the dummy layers 511 and 513 are formed on the substrate. The dummy layers 511 and 513 define the cutting boundaries of the first diffusion region 201 and the third diffusion region 203 when the first cell 10-1 is selected for cell abutment arrangement in a layout design. The dummy layers 511 and 513 may be polysilicon layers that are fabricated with polysilicon gates using the same process. As shown in FIG. 3A, in some embodiments, the contacts 411 and 414 are adjacent to the dummy layers 511, while the contacts 413 and 416 are adjacent to the dummy layers 513. The dummy layers 511 and 513 may extend in the second direction D2 (such as the Y-direction). In this example, the dummy layers 511 and 513 extend parallel to the longitudinal axis of first gate structure 301 or the longitudinal axis of first gate structure 303.

Similarly, in the second cell 10-2 of some embodiments, the dummy layers 521 and 523 are formed on the substrate. The dummy layers 521 and 523 define the cutting boundaries of the second diffusion region 202 and the fourth diffusion region 204 when the second cell 10-2 is selected for cell abutment arrangement in a layout design. The dummy layers 521 and 523 may be polysilicon layers that are fabricated with polysilicon gates using the same process. As shown in FIG. 3A, in some embodiments, the contacts 421 and 424 are adjacent to the dummy layers 521, while the contacts 423 and 426 are adjacent to the dummy layers 523. The dummy layers 521 and 523 may extend in the second direction D2 (such as the Y-direction). In this example, the dummy layers 521 and 523 extend parallel to the longitudinal axis of second gate structure 302 or the longitudinal axis of second gate structure 304.

FIG. 3B is a top view of the semiconductor device including the first cell 10-1 and the second cell 10-2 of FIG. 3A in the abutment arrangement, in accordance with some embodiments of the present disclosure. It should be noted that similar or the same reference numbers are used to designate the similar or the identical features/components in FIG. 3A and FIG. 3B, and the details of the similar or the identical features/components are not repeated herein.

In FIG. 3B, an abutment arrangement using single diffusion break (SDB) layout design is exemplified in this embodiment. Single diffusion break (SDB) acts as an efficient area-scaling enabler for current CMOS technology nodes. In the abutment arrangement, the dummy layer 511 of the first cell 10-1 overlaps the dummy layer 521 of the second cell 10-2 in the SDB layout design. In addition, in the abutment arrangement, the dummy layer 511 (or the dummy layer 521) overlaps the first part 2011 of the first diffusion region 201, the second part 2021 of the second diffusion region 202, the third part 2031 of the third diffusion region 203 and the fourth part 2041 of the fourth diffusion region 204. The first part 2011 of the first diffusion region 201 abuts the second part 2021 of the second diffusion region 202. The third part 2031 of the third diffusion region 203 abuts the fourth part 2041 of the fourth diffusion region 204, as shown in FIG. 3B.

According to an initial layout with a modified cut pattern, the dummy layers 513 and 511 define the cutting boundaries of the first cell 10-1, and the dummy layers 523 and 521 define the cutting boundaries of the second cell 10-2, when the first cell 10-1 and the second cell 10-2 are selected for cell abutment arrangement in an initial layout design. That is, an initial cut pattern CP_1 of the initial layout design includes the dummy layers 513, 523 and the overlapped dummy layers 511 and 521 in FIG. 3B.

Referring to FIG. 3B, the semiconductor device includes the first conductive rail 611 and the second conductive rail 612. The first conductive rail 611 and the second conductive rail 612 are disposed outsides the diffusion regions (e.g., the diffusion regions 201, 202, 203 and 204). Specifically, the first conductive rail 611 is disposed near the first diffusion region 201 and the second diffusion region 202. The second conductive rail 612 is disposed near the third diffusion region 203 and the fourth diffusion region 204.

In some embodiments, the first conductive rail 611 is configured to electrically connect a positive power supply line (e.g., a VCC line), and the second conductive rail 612 is configured to electrically connect a grounding line (e.g., a VSS line). The first conductive rail 611 can be referred to as the first power rail, and the second conductive rail 612 can be referred to as the second power rail. The first conductive rail 611 and the second conductive rail 612 may extend in the first direction D1 (such as the X-direction). In this example, the first conductive rail 611 extends parallel to the longitudinal axis of the first diffusion region 201 and the longitudinal axis of the second diffusion region 202. The second conductive rail 612 extends parallel to the longitudinal axis of the third diffusion region 203 and the longitudinal axis of the fourth diffusion region 204.

As shown in FIG. 3B, in some embodiments, the contact 411 (e.g. source/drain contact) of the first cell 10-1 extends to the first conductive rail 611 and electrically connects the first conductive rail 611 through the conductive via 711. Accordingly, the source/drain region of a PMOS transistor (having the first gate structure 301 in the n-type first diffusion region 201) is coupled to the positive power supply line (e.g., a VCC line) through the first conductive rail 611 and the corresponding contact 411.

Similarly, the contact 413 (e.g. source/drain contact) of the first cell 10-1 extends to the first conductive rail 611 and electrically connects the first conductive rail 611 through the conductive via 713. Accordingly, the source/drain region of another PMOS transistor (having the first gate structure 303 in the n-type first diffusion region 201) is coupled to the positive power supply line (e.g., a VCC line) through the first conductive rail 611 and the corresponding contact 413, in accordance with some embodiments of the present disclosure.

In addition, in some embodiments, the contact 416 (e.g. source/drain contact) of the first cell 10-1 extends to the second conductive rail 612 and electrically connects the second conductive rail 612 through the conductive via 716. Accordingly, the source/drain region of a NMOS transistor (having the first gate structure 303 in the p-type third diffusion region 203) is coupled to the grounding line (e.g., a VSS line) through the second conductive rail 612 and the corresponding contact 416, in accordance with some embodiments of the present disclosure.

As shown in FIG. 3B, in some embodiments, the contact 421 (e.g. source/drain contact) of the second cell 10-2 extends to the first conductive rail 611 and electrically connects the first conductive rail 611 through the conductive via 721. Accordingly, the source/drain region of a PMOS transistor (having the second gate structure 302 in the n-type second diffusion region 202) is coupled to the positive power supply line (e.g., a VCC line) through the first conductive rail 611 and the corresponding contact 421.

Similarly, the contact 423 (e.g. source/drain contact) of the second cell 10-2 extends to the first conductive rail 611 and electrically connects the first conductive rail 611 through the conductive via 723. Accordingly, the source/drain region of another PMOS transistor (having the second gate structure 304 in the n-type second diffusion region 202) is coupled to the positive power supply line (e.g., a VCC line) through the first conductive rail 611 and the corresponding contact 423, in accordance with some embodiments of the present disclosure.

In addition, in some embodiments, the contact 424 (e.g. source/drain contact) of the second cell 10-2 extends to the second conductive rail 612 and electrically connects the second conductive rail 612 through the conductive via 724. Accordingly, the source/drain region of a NMOS transistor (having the second gate structure 302 in the p-type fourth diffusion region 204) is coupled to the grounding line (e.g., a VSS line) through the second conductive rail 612 and the corresponding contact 424, in accordance with some embodiments of the present disclosure.

As shown in FIG. 3B, according to an initial structure of the semiconductor device 100S-I, the diffusions regions of the adjacent cells will be separated from each other after a patterning process is performed. The spacing between the diffusions regions of the adjacent cells corresponds to the position of the dummy layer 511(/the dummy layer 521). Accordingly, if the initial cut pattern of the initial layout is implemented, the first diffusion region 201 of the first cell 10-1 will be insulatively separated from the second diffusion region 202 of the second cell 10-2, and the third diffusion region 203 of the first cell 10-1 will be insulatively separated from the fourth diffusion region 204 of the second cell 10-2 by an isolation layer (not shown) that corresponds to the position of the dummy layer 511(/the dummy layer 521).

Specifically, shown in FIG. 3B, the first part 2011 of the first diffusion region 201 and the second part 2021 of the second diffusion region 202 will be removed to form a trench (not shown) in the substrate 100 in the subsequent manufacturing process, and the trench is filled with one or more dielectric materials to form an isolation layer, so that the remaining portion of the first diffusion region 201 is insulatively separated from the remaining portion of the second diffusion region 202 by the isolation layer, if the initial cut pattern of the initial layout is implemented. Similarly, the third part 2031 of the third diffusion region 203 abuts the fourth part 2041 of the fourth diffusion region 204. The third part 2031 of the third diffusion region 203 and the fourth part 2041 of the fourth diffusion region 204 will be removed in the subsequent manufacturing process, so that the remaining portion of the third diffusion region 203 is insulatively separated from the remaining portion of the fourth diffusion region 204, if the initial cut pattern of the initial layout is implemented. In addition, the isolation layer for separating the diffusion regions can be formed before or after forming the polysilicon layers that correspond to the positions of the first gate structures 301 and 303, the second gate structures 302 and 304 and the dummy layers 511/521, 513 and 523. The present disclosure is not limited to the method provided herein.

However, the adjacent contacts of the adjacent cells that are at opposite sides of the dummy layer 511 (or the dummy layer 521) and equipotential during operation of the semiconductor device may induce undesirable stress if the diffusion regions under the adjacent contacts are separated by the isolation (e.g. STI). The semiconductor device layout design modification method in accordance with some embodiments can solve the stress issue and enhance the electrical characteristics of the cells, thereby improving an overall electrical performance of the semiconductor device.

Referring to FIG. 3B, in some embodiments, the contact 411 (also referred to as “the first contact 411”) of the first cell 10-1 is electrically connected to the first conductive rail 611 (e.g. through the conductive via 711), as shown in FIG. 3B. Also, the contact 421 (also referred to as “the second contact 421”) of the second cell 10-2 is electrically connected to the first conductive rail 611 (e.g. through the conductive via 721). When the semiconductor device is in operation, the first contact 411 of the first cell 10-1 and the second contact 421 of the second cell 10-2 are equipotential because they are connected to the same conductive rail (i.e. the first conductive rail 611). If the first diffusion region 201 under the first contact 411 is insulatively separated from the second diffusion region 202 under the second contact 421 according to the initial cut pattern of the initial layout, it would cause LOD (length of diffusion) effect on the cells (i.e. the first cell 10-1 and the second cell 10-2) of the semiconductor device due to the undesired stress on the transistors of the cells. Consequently, the electrical performance of the cells (such as the standard cells) of the semiconductor device 100S-I that is fabricated based on the initial cut pattern of the initial layout would be deteriorated.

On the contrary, the adjacent contacts of the adjacent cells that are at opposite sides of the dummy layer 511 (or the dummy layer 521) and non-equipotential during operation of the semiconductor device should be disposed over the separated diffusion regions for electrical isolation. For example, the contact 414 (also referred to as “the third contact 414”) of the first cell 10-1 is not connected to the second conductive rail 612, while the contact 424 (also referred to as “the fourth contact 424”) of the second cell 10-2 is electrically connected to the second conductive rail 612 (e.g. through the conductive via 724), as shown in FIG. 3B. When the semiconductor device is in operation, the third contact 414 of the first cell 10-1 and the fourth contact 424 of the second cell 10-2 are not equipotential. It is required that the third diffusion region 203 under the third contact 414 is insulatively separated from the fourth diffusion region 204 under the fourth contact 424 to prevent current leakage. Accordingly, the part of the dummy layer 511 (or the dummy layer 521) that is positioned for cutting parts of the diffusion regions, based on the initial cut pattern of the initial layout, remains in a modified pattern of a modified layout in accordance with some embodiment.

According to the embodiments of the present invention, a semiconductor device having the cells with optimized configurations of the diffusion regions can be provided. FIG. 4 is a top view of a semiconductor device including cells with optimized configurations in an abutment arrangement, in accordance with some embodiments of the present disclosure. In some embodiments, the initial structure of the semiconductor device 100S-I of FIG. 3B can be modified by the operations S22 and S23 of FIG. 2 (see FIG. 5A-FIG. 5D to be described later) of the layout design modification method, thereby forming a modified structure of the semiconductor device 100S-M as shown in FIG. 4.

In addition, it should be noted that similar or the same reference numbers are used to designate the similar or the identical features/components in the initial semiconductor device 100S-I of FIG. 3B and in the modified semiconductor device 100S-M of FIG. 4, and the details of the similar or the identical features/components (such as the structures, materials and configurations thereof) may not repeated herein.

Referring to FIG. 4, in some embodiments, a modified semiconductor device 100S-M includes the first cell 10-1 and the second cell 10-2. The first cell 10-1 includes the first diffusion region 201 and the third diffusion region 203 in the substrate 100. The second cell 10-2 includes the second diffusion region 202 and the fourth diffusion region 204 in the substrate 100. As shown in the first cell 10-1 of FIG. 4, the first diffusion region 201 is separated from the third diffusion region 203 by the isolation region 102 (such as STI). As shown in the second cell 10-2 of FIG. 4, the second diffusion region 202 is separated from the fourth diffusion region 204 by the isolation region 102 (such as STI).

In this example, the first diffusion region 201 has the opposite conductivity type of the third diffusion region 203 in the first cell 10-1 of FIG. 4. The first cell 10-1 of FIG. 4 is configured as a standard complementary metal oxide semiconductor (CMOS) cell; that is, the first cell 10-1 includes PMOS transistors and NMOS transistors. Similarly, the second diffusion region 202 has the opposite conductivity type of the fourth diffusion region 204 in the second cell 10-2 of FIG. 4. The second cell 10-2 of FIG. 4 is configured as a standard complementary metal oxide semiconductor (CMOS) cell; that is, the second cell 10-2 includes PMOS transistors and NMOS transistors.

In some embodiments, the first cell 10-1 further includes the first gate structures 301 and 303 that extend across the first diffusion region 201 and the third diffusion region 203. The second cell 10-2 further includes the second gate structures 302 and 304 that extend across the second diffusion region 202 and the fourth diffusion region 204. As shown in FIG. 4, the first gate structures 301 and 303 are spaced apart from each other in the first direction D1 and extend in the second direction D2. The second gate structures 302 and 304 are spaced apart from each other in the first direction D1 and extend in the second direction D2.

In some embodiments, the first cell 10-1 of FIG. 4 further includes the contacts 411, 412 and 413 disposed over the first diffusion region 201, and the contacts 414, 415 and 416 disposed over the second diffusion region 203. The contacts 411, 412, 413, 414, 415 and 416 are electrically connected to the underlying source/drain region (not shown), and can be referred to as the source/drain contacts. As shown in FIG. 4, the contacts 411, 412, 413, 414, 415 and 416 are spaced apart from each other. The contacts 411, 412, 413, 414, 415 and 416 may extend in the second direction D2 (such as the Y-direction).

In some embodiments, the second cell 10-2 of FIG. 4 further includes the contacts 421, 422 and 423 disposed over the second diffusion region 202, and the contacts 424, 425 and 426 disposed over the fourth diffusion region 204. The contacts 421, 422, 423, 424, 425 and 426 are electrically connected to the underlying source/drain region (not shown), and can be referred to as the source/drain contacts. As shown in FIG. 4, the contacts 421, 422, 423, 424, 425 and 426 are spaced apart from each other. The contacts 421, 422, 423, 424, 425 and 426 may extend in the second direction D2 (such as the Y-direction).

In addition, in the first cell 10-1 of FIG. 4, the contacts 411 and 413 over the first diffusion region 201 are electrically connected to the first conductive rail 611 through the conductive vias 711 and 713, respectively. The contact 416 over the third diffusion region 203 is electrically connected to the second conductive rail 612 through the conductive via 716. In the second cell 10-2 of FIG. 4, the contacts 421 and 423 over the second diffusion region 202 are electrically connected to the first conductive rail 611 through the conductive vias 721 and 723, respectively. The contact 424 over the fourth diffusion region 204 is electrically connected to the second conductive rail 612 through the conductive via 724, in accordance with some embodiments of the present disclosure. In some embodiments, the first conductive rail 611 is configured to electrically connect a positive power supply line (e.g., a VCC line), and the second conductive rail 612 is configured to electrically connect a grounding line (e.g., a VSS line). The first conductive rail 611 can be referred to as the first power rail, and the second conductive rail 612 can be referred to as the second power rail.

According to a modified layout with a modified cut pattern of some embodiments, the dummy layers 513 and 531 define the cutting boundaries of the first cell 10-1, and the dummy layers 523 and 531 define the cutting boundaries of the second cell 10-2, when the first cell 10-1 and the second cell 10-2 are selected for cell abutment arrangement in a layout design. That is, a modified cut pattern CP_2 of the modified layout design includes the dummy layers 513, 523 and 531. The dummy layers 513, 523 and 531 may extend in the second direction D2 (such as the Y-direction). In this example, the dummy layers 513, 523 and 531 extend parallel to the longitudinal axis of the first gate structures 301 and 303 or the longitudinal axis of the second gate structures 302 and 304.

In some embodiments, the contact 411 (also referred to as “the first contact 411”) of the first cell 10-1 is electrically connected to the first conductive rail 611 (e.g. through the conductive via 711), and the contact 421 (also referred to as “the second contact 421”) of the second cell 10-2 is electrically connected to the first conductive rail 611 (e.g. through the conductive via 721), as shown in FIG. 4. When the semiconductor device is in operation, the first contact 411 of the first cell 10-1 and the second contact 421 of the second cell 10-2 are equipotential since they are connected to the same conductive rail (i.e. the first conductive rail 611). Therefore, according to the modified layout, the first diffusion region 201 under the first contact 411 and the second diffusion region 202 under the second contact 421 are not covered by the dummy layer 531. That is, the first diffusion region 201 is not separated from the second diffusion region 202 in a subsequent manufacturing process. After the modified layout of the abutment arrangement is implemented, the first diffusion region 201 and the second diffusion region 202 of a semiconductor device form a continuous diffusion region 22. Another gate structure 310 is formed over the continuous diffusion region 22. In the subsequent processes, the polysilicon layers that correspond to the positions of the first gate structures 301 and 303, the second gate structures 302 and 304 and the gate structure 310 are replaced by metal to form metal gates in accordance with some embodiments. When the semiconductor device is in operation, the equipotential first contact 411 of the first cell 10-1 and the second contact 421 of the second cell 10-2 are positioned over the continuous diffusion region 22, thereby mitigating the LOD (length of diffusion) effect induced by the isolation stress on the transistors of the cells.

In addition, in some embodiments, the contact 414 (also referred to as “the third contact 414”) of the first cell 10-1 is not connected to the second conductive rail 612, while the contact 424 (also referred to as “the fourth contact 424”) of the second cell 10-2 is electrically connected to the second conductive rail 612 (e.g. through the conductive via 724), as shown in FIG. 4. Therefore, according to the modified layout, the dummy layer 531 of FIG. 4 is positioned between the third contact 414 of the first cell 10-1 and the fourth contact 424 of the second cell 10-2. As shown in FIG. 4, the dummy layer 531 corresponds to the third diffusion region 203 of the first cell 10-1 and the fourth diffusion region 204 of the second cell 10-2. Specifically, the dummy layer 531 overlaps the third part 2031 of the third diffusion region 203 and the fourth part 2041 of the fourth diffusion region 204. The third part 2031 of the third diffusion region 203 abuts the fourth part 2041 of the fourth diffusion region 204. In a subsequent manufacturing process, the third part 2031 of the third diffusion region 203 and the fourth part 2041 of the fourth diffusion region 204 are removed (e.g. by forming a trench, and the trench is then filled with one or more dielectric materials to form an isolation layer), so that the remaining portion of the third diffusion region 203 is insulatively separated from the remaining portion of the fourth diffusion region 204, after the modified layout is implemented.

According to the embodiments of the present disclosure, the modified semiconductor device (such as the semiconductor device 100S-M) can prevent the isolation stress between the diffusion regions under the equipotential contacts of adjacent cells when the modified semiconductor device is in operation, thereby migrate the LOD (length of diffusion) effect on the cells of the modified semiconductor device. Also, other diffusion regions that are required to be separated from each other for electrical isolation remain separate in the modified semiconductor device 100S-M. Therefore, the electrical performance of the cells (such as the standard cells) of the modified semiconductor device 100S-M can be optimized and significantly improved.

FIG. 5A-FIG. 5D illustrate a method of generating a modified layout in the abutment arrangement for forming a semiconductor device in accordance with some embodiments of the present disclosure. It should be noted that the present disclosure is not limited to the method provided herein. Those operations described in FIG. 5A-FIG. 5D are merely for providing one example of generating a modified layout in the abutment arrangement. Other examples for verifying adjacent contacts that are equipotential when the semiconductor device is in operation are also applicable for implementing the embodiments of the present disclosure.

In addition, it should be noted that similar or the same reference numbers are used to designate the similar or the identical features/components in the semiconductor devices of FIG. 3B, FIG. 4 and FIG. 5A-FIG. 5D, and the details of the similar or the identical features/components (such as the structures, materials and configurations thereof) may not repeated herein.

In this exemplified method, several identification marks are provided to facilitate the verification of adjacent contacts that are equipotential when the semiconductor device is in operation. The identification marks may be arranged so that they correspond to the dummy layers (such as the dummy layers 511 and 513 of the first cell 10-1 and the dummy layers 521 and 523 of the second cell 10-2).

Corresponding to operation S22 of FIG. 2, FIG. 5A is a top view of two cells with identification marks before an abutment arrangement is implemented, in accordance with some embodiments of the present disclosure. FIG. 5B is a top view of the semiconductor device including the cells with identification marks of FIG. 5A in the abutment arrangement, in accordance with some embodiments of the present disclosure.

Referring to FIG. 5A, in some embodiments, the identification marks 801, 802 and 803 are arranged so that they correspond to the dummy layers of the first cell 10-1 and close to the contacts that are electrically connected to the conductive rails (such as the first conductive rail 611 and the second conductive rail 612). The identification marks 801, 802 and 803 may extend in the second direction D2 (such as the Y-direction). In some embodiments, the identification marks 801, 802 and 803 extend parallel to the longitudinal axis of dummy layer 511 and the longitudinal axis of dummy layer 513 of the first cell 10-1.

Specifically, the identification mark 801 is arranged so that it corresponds to the dummy layer 513 of the first cell 10-1 (such as the upper portion of the dummy layer 513), as shown in FIG. 5A. In this example, the width WM of the identification mark 801 is half of the width WP of the dummy layer 513. The identification mark 801 is arranged closer to the contact 413 of the first cell 10-1. For example, the right side of the identification mark 801 is aligned with the right side of the dummy layer 513 when viewed from the top of the first cell 10-1.

In FIG. 5A, the identification mark 802 is arranged so that it corresponds to the dummy layer 513 of the first cell 10-1 (such as the lower portion of the dummy layer 513). In this example, the width WM of the identification mark 802 is half of the width WP of the dummy layer 513. The identification mark 802 is arranged closer to the contact 416 of the first cell 10-1. For example, the right side of the identification mark 802 is aligned with the right side of the dummy layer 513 when viewed from the top of the first cell 10-1.

In FIG. 5A, the identification mark 803 is arranged so that it corresponds to the dummy layer 511 of the first cell 10-1 (such as the upper portion of the dummy layer 513). In this example, the width of the identification mark 803 is half of the width of the dummy layer 513. In some embodiments, the widths of the identification marks 801, 802 and 803 are identical. Also, the identification mark 803 is arranged closer to the contact 411 of the first cell 10-1. For example, the left side of the identification mark 803 is aligned with the left side of the dummy layer 511 when viewed from the top of the first cell 10-1.

It should be noted that no identification mark is labeled adjacent to the contact 414 of the first cell 10-1 in this exemplified method, wherein the contact 414 is not electrically connected to the conductive rail (such as the second conductive rail 612).

Similarly, as shown in FIG. 5A, the identification marks 804, 805 and 806 are arranged so that they correspond to the dummy layers of the second cell 10-2 and close to the contacts that are electrically connected to the conductive rails (such as the first conductive rail 611 and the second conductive rail 612). The identification marks 804, 805 and 806 may extend in the second direction D2 (such as the Y-direction). In some embodiments, the identification marks 804, 805 and 806 extend parallel to the longitudinal axis of dummy layer 521 and the longitudinal axis of dummy layer 523 of the second cell 10-2 in FIG. 5A.

Specifically, the identification mark 804 is arranged so that it corresponds to the dummy layer 521 of the second cell 10-2 (such as the upper portion of the dummy layer 521), as shown in FIG. 5A. In this example, the width WM of the identification mark 804 is half of the width WP of the dummy layer 521. The identification mark 804 is arranged closer to the contact 421 of the second cell 10-2. For example, the right side of the identification mark 804 is aligned with the right side of the dummy layer 521 when viewed from the top of the second cell 10-2.

In FIG. 5A, the identification mark 805 is arranged so that it corresponds to the dummy layer 521 of the second cell 10-2 (such as the lower portion of the dummy layer 521). In this example, the width WM of the identification mark 805 is half of the width WP of the dummy layer 521. The identification mark 805 is arranged closer to the contact 424 of the second cell 10-2. For example, the right side of the identification mark 805 is aligned with the right side of the dummy layer 521 when viewed from the top of the second cell 10-2.

In FIG. 5A, the identification mark 806 is arranged so that it corresponds to the dummy layer 523 of the second cell 10-2 (such as the upper portion of the dummy layer 523). In this example, the width of the identification mark 806 is half of the width of the dummy layer 523. In some embodiments, the widths of the identification marks 804, 805 and 806 are identical. Also, the identification mark 806 is arranged closer to the contact 423 of the second cell 10-2. For example, the left side of the identification mark 806 is aligned with the left side of the dummy layer 523 when viewed from the top of the second cell 10-2, as shown in FIG. 5A.

It should be noted that no identification mark is labeled adjacent to the contact 426 of the second cell 10-2 in this exemplified method, wherein the contact 426 is not electrically connected to the conductive rail (such as the second conductive rail 612).

Referring to FIG. 5B, in some embodiments, a single diffusion break (SDB) layout design is adopted for arranging the first cell 10-1 and the second cell 10-2. In the abutment arrangement, the dummy layer 511 of the first cell 10-1 overlaps the dummy layer 521 of the second cell 10-2. Accordingly, the identification mark 803 corresponding to the left side of the dummy layer 511 joins the identification mark 804 corresponding to the right side of the dummy layer 521 together, thereby forming an integrated mark 81M. In some embodiments, the width WI of the integrated mark 81M is equal to the width WP of the dummy layer 511 (or the dummy layer 521).

As shown in FIG. 5B, in some embodiments, each of the identification marks 801 and 802 corresponding to the right side of the dummy layer 513 does not join any identification mark and remains in a half-width overlap arrangement on the dummy layer 513 after the abutment arrangement. The identification mark 805 corresponding to the right side of the dummy layer 511 does not join any identification mark and remains in a half-width overlap arrangement on the dummy layer 513 after the abutment arrangement. The identification mark 806 corresponding to the left side of the dummy layer 523 does not join any identification mark and remains in a half-width overlap arrangement on the dummy layer 523 in the abutment arrangement. In some embodiments, the modified layout does not take account of these identification marks 801, 802, 805 and 806.

Corresponding to operation S23 of FIG. 2, FIG. 5C is a top view of two cells with an integrated mark for altering the initial layout of FIG. 3B in an abutment arrangement, in accordance with some embodiments of the present disclosure.

Referring to FIG. 5C, the integrated mark 81M (having the width WI equal to the width WP of the dummy layer 511) corresponding to the upper portion of the dummy layer 511 remains for altering the initial layout, while the identification marks 801, 802, 805 and 806 that each has a half width of the dummy layer 513/511/523 are eliminated.

FIG. 5D is a top view of a modified semiconductor device including cells (such as the first cell 10-1 and the second cell 10-2) with optimized configurations in an abutment arrangement, in accordance with some embodiments of the present disclosure. The modified semiconductor device is configured based on a modified layout.

In addition, it should be noted that similar or the same reference numbers are used to designate the similar or the identical features/components in FIG. 4 and FIG. 5D, and the details of the similar or the identical features/components (such as the structures, materials and configurations thereof) may not repeated herein.

Referring to FIG. 5C and FIG. 5D, in some embodiments, one (or more) cutting portion(s) of the initial cut pattern of the initial layout (e.g. the initial cut pattern CP_1 in FIG. 3B) is eliminated to generate a modified layout with a modified pattern. For example, the cutting portion of the initial layout that corresponds to the integrated mark 81M of FIG. 5C is eliminated after the initial layout is altered. In this exemplified embodiment, the integrated mark 81M corresponds to the first part 2011 (FIG. 3B) of the first diffusion region 201 and the second part 2021 (FIG. 3B) of the second diffusion region 202. The first part 2011 of the first diffusion region 201 and the second part 2021 of the second diffusion region 202 are not removed after the modified layout is implemented. Accordingly, a modified layout is generated by uncutting the diffusion regions under the adjacent contacts that are equipotential when the semiconductor device is in operation. As shown in FIG. 5D, in some embodiments, the diffusion regions (such as the diffusion regions 201 and 202) under the adjacent contacts (such as the contacts 411 and 421) that are equipotential during operation adjoin and form a continuous diffusion region 22 in the modified layout. After the modified layout is implemented, another gate structure 310 is formed over the continuous diffusion region 22 and positioned in a region that corresponds to the integrated mark 81M (FIG. 5C). In the subsequent processes, the polysilicon layers that correspond to the positions of the first gate structures 301 and 303, the second gate structures 302 and 304 and the gate structure 310 are replaced by metal gates in accordance with some embodiments.

According to some embodiments described above, a modified semiconductor device, the method of forming the modified semiconductor device and a layout design modification method have several advantages. In a layout design modification method of some embodiments, the diffusion regions below adjacent contacts, which are disposed in different cells and equipotential when the semiconductor device is in operation, are uncut and form a continuous diffusion region in the abutment arrangement. The LOD (length of diffusion) effect on the cells of the modified semiconductor device in accordance with some embodiments of the present disclosure can be mitigated due to elimination of isolation stress on the cells. Therefore, the electrical performance of the cells (such as the standard cells) of the modified semiconductor device in accordance with some embodiments of the present disclosure can be optimized and significantly improved.

In one exemplary aspect, the present disclosure is directed to a semiconductor device. The semiconductor device includes a substrate, a first cell and a second cell on the substrate. The first cell includes a first diffusion region in the substrate, a first gate structure over the first diffusion region, and a first contact over the first diffusion region. The first contact is disposed on one side of the first gate structure. The second cell is adjacent to the first cell. The second cell includes a second diffusion region in the substrate, a second gate structure over the second diffusion region and a second contact over the second diffusion region. The second contact is positioned on one side of the second gate structure. The second contact of the second cell is adjacent to the first contact of the first cell. Also, the first contact and the second contact are equipotential when the semiconductor device is in operation. According to the embodiments, the second diffusion region and the first diffusion region form a continuous diffusion region.

In one exemplary aspect, the present disclosure is directed to a method of forming a semiconductor device. A substrate is provided. A first cell is formed. The first cell includes a first diffusion region in the substrate, a first gate structure over the first diffusion region and a first contact over the first diffusion region. The first contact is disposed on one side of the first gate structure. A second cell is formed adjacent to the first cell. The second cell includes a second diffusion region in the substrate, wherein the second diffusion region and the first diffusion region form a continuous diffusion region. The second cell further includes a second gate structure over the second diffusion region and a second contact over the second diffusion region. The second contact is disposed on one side of the second gate structure. The second contact is adjacent to the first contact of the first cell. The first contact and the second contact are equipotential when the semiconductor device is in operation.

In one exemplary aspect, the present disclosure is directed to a semiconductor device layout design modification method. The layout design modification method includes receiving an initial layout for cutting adjacent diffusion regions of a first cell and a second cell of a semiconductor device; verifying a first contact of the first cell and a second contact of the second cell that is arranged adjacent to the first contact using a processor, wherein the first contact and the second contact are equipotential when the semiconductor device is in operation; and altering the initial layout to generate a modified layout by uncutting a first diffusion region under the first contact and a second diffusion region under the second contact using the processor, wherein the first diffusion region and the second diffusion region form a continuous diffusion region in the modified layout.

It should be noted that the details of the structures and fabrications of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a first cell, comprising:
a first diffusion region in the substrate;
a first gate structure over the first diffusion region; and
a first contact over the first diffusion region and on one side of the first gate structure; and
a second cell adjacent to the first cell, the second cell comprising:
a second diffusion region in the substrate, wherein the second diffusion region and the first diffusion region form a continuous diffusion region;
a second gate structure over the second diffusion region; and
a second contact over the second diffusion region and on one side of the second gate structure, wherein the second contact is adjacent to the first contact of the first cell,
wherein the first contact and the second contact are equipotential when the semiconductor device is in operation.

2. The semiconductor device as claimed in claim 1, further comprising:
a first conductive rail, adjacent to the first diffusion region and the second diffusion region,
wherein the first contact of the first cell and the second contact of the second cell are electrically connected to the first conductive rail.

3. The semiconductor device as claimed in claim 2, wherein the first conductive rail extends parallel to a longitudinal axis of the first diffusion region or the second diffusion region.

4. The semiconductor device as claimed in claim 2, wherein the first cell comprises a first source contact and a first drain contact at opposite sides of the first gate structure, wherein the first source contact is electrically connected to the first conductive rail.

5. The semiconductor device as claimed in claim 2, wherein the second cell comprises a second source contact and a second drain contact at opposite sides of the second gate structure, wherein the second source contact is electrically connected to the first conductive rail.

6. The semiconductor device as claimed in claim 1, wherein the first diffusion region of the first cell and the second diffusion region of the second cell have the same conductivity type.

7. The semiconductor device as claimed in claim 1, wherein the first cell further comprises:
a third diffusion region in the substrate and separated from the first diffusion region; and
a third contact over the third diffusion region,
wherein a conductivity type of the third diffusion region is the opposite of a conductivity type of the first diffusion region.

8. The semiconductor device as claimed in claim 7, wherein the first gate structure extends across the third diffusion region of the first cell, and the third contact is disposed on one side of the first gate structure.

9. The semiconductor device as claimed in claim 7, wherein the second cell further comprises:
a fourth diffusion region in the substrate and separated from the second diffusion region; and
a fourth contact over the fourth diffusion region,
wherein a conductivity type of the fourth diffusion region is the opposite of a conductivity type of the second diffusion region, and
wherein the fourth contact of the second cell and the third contact of the first cell are non-equipotential when the semiconductor device is in operation.

10. The semiconductor device as claimed in claim 9, wherein the second gate structure extends across the fourth diffusion region of the second cell, and the fourth contact is disposed on one side of the second gate structure.

11. The semiconductor device as claimed in claim 9, further comprising:
a second conductive rail, adjacent to the third diffusion region and the fourth diffusion region,
wherein the third contact or the fourth contact is electrically connected to the second conductive rail, and the other of the third contact or the fourth contact is electrically isolated from the second conductive rail.

12. The semiconductor device as claimed in claim 11, wherein the third diffusion region of the first cell and the fourth diffusion region of the second cell have the same conductivity type.

13. The semiconductor device as claimed in claim 1, wherein another gate structure is formed over the continuous diffusion region and extends parallel to the first gate structure and the second gate structure.

14. A method of forming a semiconductor device, comprising:
providing a substrate;
forming a first cell, wherein the first cell comprises:
a first diffusion region in the substrate;
a first gate structure over the first diffusion region; and
a first contact over the first diffusion region and on one side of the first gate structure; and
forming a second cell adjacent to the first cell, wherein the second cell comprises:
a second diffusion region in the substrate, wherein the second diffusion region and the first diffusion region form a continuous diffusion region;
a second gate structure over the second diffusion region; and
a second contact over the second diffusion region and on one side of the second gate structure, wherein the second contact is adjacent to the first contact of the first cell, and the first contact and the second contact are equipotential when the semiconductor device is in operation.

15. The method of forming the semiconductor device as claimed in claim 14, further comprising:
forming a first conductive rail that extends parallel to a longitudinal axis of the first diffusion region or the second diffusion region,
wherein the first contact of the first cell and the second contact of the second cell are electrically connected to the first conductive rail.

16. The method of forming the semiconductor device as claimed in claim 15, wherein the first cell comprises a first source contact and a first drain contact at opposite sides of the first gate structure, wherein the first source contact is electrically connected to the first conductive rail.

17. The method of forming the semiconductor device as claimed in claim 15, wherein the second cell comprises a second source contact and a second drain contact at opposite sides of the second gate structure, wherein the second source contact is electrically connected to the first conductive rail.

18. The method of forming the semiconductor device as claimed in claim 14, wherein the first diffusion region of the first cell and the second diffusion region of the second cell have the same conductivity type.

19. The method of forming the semiconductor device as claimed in claim 14, wherein the first cell further comprises:
a third diffusion region in the substrate and separated from the first diffusion region; and
a third contact over the third diffusion region,
wherein a conductivity type of the third diffusion region is the opposite of a conductivity type of the first diffusion region.

20. The method of forming the semiconductor device as claimed in claim 19, wherein the first gate structure extends across the third diffusion region of the first cell, and the third contact is disposed on one side of the first gate structure.

21. The method of forming the semiconductor device as claimed in claim 19, wherein the second cell further comprises:
a fourth diffusion region in the substrate and separated from the second diffusion region; and
a fourth contact over the fourth diffusion region,
wherein the conductivity type of the fourth diffusion region is the opposite of the conductivity type of the second diffusion region, and
wherein the fourth contact of the second cell and the third contact of the first cell are non-equipotential when the semiconductor device is in operation.

22. The method of forming the semiconductor device as claimed in claim 21, wherein the second gate structure extends across the fourth diffusion region of the second cell, and the fourth contact is disposed on one side of the second gate structure.

23. The method of forming the semiconductor device as claimed in claim 21, wherein the semiconductor device further comprises:
a second conductive rail that extends parallel to a longitudinal axis of the third diffusion region or the fourth diffusion region,
wherein the third contact or the fourth contact is electrically connected to the second conductive rail, and the other of the third contact or the fourth contact is electrically isolated from the second conductive rail.

24. The method of forming the semiconductor device as claimed in claim 14, wherein another gate structure is formed over the continuous diffusion region and extends parallel to the first gate structure and the second gate structure.

25. A semiconductor device layout design modification method, comprising:
receiving an initial layout for cutting adjacent diffusion regions of a first cell and a second cell of a semiconductor device;
verifying a first contact of the first cell and a second contact of the second cell that is arranged adjacent to the first contact using a processor, wherein the first contact and the second contact are equipotential when the semiconductor device is in operation; and
altering the initial layout to generate a modified layout by uncutting a first diffusion region under the first contact and a second diffusion region under the second contact using the processor, wherein the first diffusion region and the second diffusion region form a continuous diffusion region in the modified layout.

26. The semiconductor device layout design modification method as claimed in claim 25, wherein the initial layout comprises a cutting portion corresponding to a first part of the first diffusion region and a second part of the second diffusion region, and the first part of the first diffusion region abuts the second part of the second diffusion region.

27. The semiconductor device layout design modification method as claimed in claim 26, wherein altering the initial layout to generate the modified layout comprises:
eliminating the cutting portion of the initial layout that corresponds to the first part of the first diffusion region and the second part of the second diffusion region,
wherein the first part abuts the second part, so that the first diffusion region and the second diffusion region form a continuous diffusion region in the modified layout.

28. The semiconductor device layout design modification method as claimed in claim 27, wherein the semiconductor device further comprises:
another gate structure over the continuous diffusion region and extending parallel to a first gate structure of the first cell and a second gate structure of the second cell.

29. The semiconductor device layout design modification method as claimed in claim 25, wherein the semiconductor device further comprises:
a first conductive rail that extends parallel to a longitudinal axis of the first diffusion region or the second diffusion region,
wherein the first contact of the first cell and the second contact of the second cell are electrically connected to the first conductive rail.

30. The semiconductor device layout design modification method as claimed in claim 25, wherein the first cell further comprises a third contact over a third diffusion region that is separated from the first diffusion region; and
the second cell further comprises a fourth contact over a fourth diffusion region that is separated from the second diffusion region,
wherein the third contact of the first cell is adjacent to the fourth contact of the second cell, and the third contact and the fourth contact are non-equipotential when the semiconductor device is in operation.

31. The semiconductor device layout design modification method as claimed in claim 30, wherein the initial layout comprises:
a cutting portion corresponding to a third part of the third diffusion region and a fourth part of the fourth diffusion region,
wherein the third part abuts the fourth part.

32. The semiconductor device layout design modification method as claimed in claim 31, wherein the cutting portion of the initial layout that corresponds to the third part of the third diffusion region and the fourth part of the fourth diffusion region remains in the modified layout.

33. The semiconductor device layout design modification method as claimed in claim 32, wherein the third part of the third diffusion region and the fourth part of the fourth diffusion region are removed in a manufacturing process, so that a remaining portion of the third diffusion region is separated from a remaining portion of the fourth diffusion region.

34. The semiconductor device layout design modification method as claimed in claim 30, wherein the semiconductor device further comprises:
a second conductive rail that extends parallel to a longitudinal axis of the third diffusion region and the fourth diffusion region,
wherein the third contact or the fourth contact is electrically connected to the second conductive rail, and the other of the third contact or the fourth contact is electrically isolated from the second conductive rail.

35. The semiconductor device layout design modification method as claimed in claim 30, wherein the third diffusion region of the first cell and the fourth diffusion region of the second cell have the same conductivity type.

36. The semiconductor device layout design modification method as claimed in claim 30, wherein a conductivity type of the third diffusion region is the opposite of a conductivity type of the first diffusion region.

37. The semiconductor device layout design modification method as claimed in claim 30, wherein a conductivity type of the fourth diffusion region is the opposite of a conductivity type of the second diffusion region.

38. The semiconductor device layout design modification method as claimed in claim 25, wherein the first diffusion region of the first cell and the second diffusion region of the second cell have the same conductivity type.

39. The semiconductor device layout design modification method as claimed in claim 25, wherein the first cell further comprises a first gate structure over the first diffusion region, and the first contact over the first diffusion region is disposed on one side of the first gate structure; and
the second cell further comprises a second gate structure over the second diffusion region, and the second contact over the second diffusion region is disposed on one side of the second gate structure.
